(19) United States
(12) Patent Application Publication
(10) Pub. No.: US 2026/0028507 A1
(43) Pub. Date: Jan. 29, 2026

(54) COMPOSITIONS FOR CHEMICAL MECHANICAL PLANARIZATION AND RELATED SYSTEMS AND RELATED METHODS

(71) Applicant: ENTEGRIS, INC., Billerica, MA (US)

(72) Inventors: Sridevi Alety, Fremont, CA (US); Aditya Dilip Verma, San Jose, CA (US); Niraj Mahadev, Milpitas, CA (US); Pankaj K. Singh, Naperville, IL (US); Rajiv K. Singh, Newberry, FL (US)

(21) Appl. No.: 19/278,684

(22) Filed: Jul. 23, 2025

Related U.S. Application Data
(60) Provisional application No. 63/674,794, filed on Jul. 23, 2024.

(51) Int. Cl. C09G 1/02; B24B 37/04; H01L 21/04; H01L 21/306

(52) U.S. Cl. CPC C09G 1/02; B24B 37/044; H01L 21/0445; H01L 21/30625

(57) ABSTRACT

Compositions, systems, and related methods for chemical mechanical planarization (CMP) polishing of silicon carbide substrates. A composition comprises at least 5% by weight of a permanganate component based on a total weight of the composition and a plurality of particles. The plurality of particles has a width percentage (WIP) less than 500.

### FIELD

The present disclosure relates to compositions for chemical mechanical planarization (CMP) and related systems and related methods.

### BACKGROUND

CMP methods are widely employed in production processes for silicon carbide semiconductor devices. Particle size distribution contributes an important role in composition properties such as fluidity, charging and particle packing on the surface of the substrate that directly influence on improving material removal, surface roughness and decreasing scratches on the substrate. A broad particle distribution has an advantage over narrow distribution during silicon carbide substrate polishing.

Broad distribution covers substrate surface more uniformly, under CMP polishing conditions (Down pressure and velocity) oxidized Silicon Carbide surface layer is removed effectively resulting higher material removal and improved surface quality.

### SUMMARY

Some embodiments relate to a composition. In some embodiments, the composition comprises at least 5% by weight of a permanganate component based on a total weight of the composition. In some embodiments, the composition comprises a plurality of particles. The plurality of particles may have a width percentage (WIP) determined according to the formula:

$$WIP = {D}_{50} / ( {D}_{90} - {D}_{10} ) * 10 \; 0 .$$

In some embodiments, WIP of the plurality of particles is less than 500.

Some embodiments relate to a system. In some embodiments, the system comprises a composition. The composition comprises at least 5% by weight of a permanganate component based on a total weight of the composition. In some embodiments, the composition comprises a plurality of particles. The plurality of particles may have a width percentage (WIP) determined according to the formula:

$$WIP = {D}_{50} / ( {D}_{90} - {D}_{10} ) * 10 \; 0 .$$

In some embodiments, WIP of the plurality of particles is less than 500.

In some embodiments, the system comprises a substrate comprising a silicon carbide layer. In some embodiments, the system comprises a chemical mechanical planarization (CMP) apparatus. In some embodiments, the CMP apparatus is configured to bring the composition and the substrate into contact to remove at least a portion of the silicon carbide layer from the substrate.

Some embodiments relate to a method. In some embodiments, the method comprises one or more of the following steps: contacting a substrate comprising a silicon carbide layer with a composition. The contacting may be under conditions sufficient to remove at least a portion of the silicon carbide layer. The composition comprises at least 5% by weight of a permanganate component based on a total weight of the composition. In some embodiments, the composition comprises a plurality of particles. The plurality of particles may have a width percentage (WIP) determined according to the formula:

$$WIP = {D}_{50} / ( {D}_{90} - {D}_{10} ) * 10 \; 0 .$$

In some embodiments, WIP of the plurality of particles is less than 500.

### DRAWINGS

FIG. 1 is a flow diagram of a method for polishing silicon carbide, according to some embodiments.

FIG. 2 is a graphical view of material removal rates for various samples with different width percentages, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure, which are intended to be illustrative, and not restrictive.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “composition” refers to any slurry, compound, formulation, and/or solution that may be used for polishing a surface.

As used herein, the term “contacting” refers to bringing two or more components into immediate or close proximity, or into direct contact.

Certain embodiments of the disclosure cover methods, processes, and compositions to increase the broad distribution over the substrate to increase the polishing conditions.

Some embodiments relate to compositions, systems, and related methods for enhancing the removal rates of silicon carbide (SiC) substrates during CMP polishing processes. The composition comprises a plurality of particles and a silicon carbide substrate. The width percentage of the plurality of particles in the composition, may be less than 500 to achieve high polishing rates during silicon carbide CMP.

The composition comprises at least 5% by weight of a permanganate component based on a total weight of the composition. The permanganate component serves as an oxidation agent to promote the oxidation of the SiC bonds on the surface of the substrate, such as a silicon carbide substrate, to be polished. In some embodiments, the composition comprises a greater amount of permanganate component than other compositions used for CMP polishing.

In some embodiments, the composition may comprise 5% to 20% by weight of the permanganate component based on a total weight of the composition, or any range or subrange between 5% and 20%. For example, in some embodiments, the permanganate component by weight based on a total weight of the composition may be 6% to 19%, 7% to 18%, 8% to 17%, 9% to 16%, 10% to 15%, 11% to 14%, or 12% to 13%. In some embodiments, the permanganate component by weight based on a total weight of the composition may be 5% to 19%, 5% to 18%, 5% to 17%, 5% to 16%, 5% to 15%, 5% to 14%, 5% to 13%, 5% to 12%, 5% to 11%, 5% to 10%, 5% to 9%, 5% to 8%, 5% to 7%, or 5% to 6%. In some embodiments, the permanganate component by weight based on a total weight of the composition may be 5% to 20%, 6% to 20%, 7% to 20%, 8% to 20%, 9% to 20%, 10% to 20%, 11% to 20%, 12% to 20%, 13% to 20%, 14% to 20%, 15% to 20%, 16% to 20%, 17% to 20%, 18% to 20%, or 19% to 20%.

In some embodiments, the composition comprises 5% to 15% by weight of the permanganate component based on the total weight of the composition, or any range or subrange between 5% and 15%. For example, in some embodiments, the permanganate component by weight based on a total weight of the composition may be 6% to 14%, 7% to 13%, 8% to 12%, or 9% to 11%. In some embodiments, the permanganate component based on the total weight of the composition may be 5% to 14%, 5% to 13%, 5% to 12%, 5% to 11%, 5% to 10%, 5% to 9%, 5% to 8%, 5% to 7%, or 5% to 6%. In some embodiments, the permanganate component based on the total weight of the plurality of particles may be 5% to 15%, 6% to 15%, 7% to 15%, 8% to 15%, 9% to 15%, 10% to 15%, 11% to 15%, 12% to 15%, 13% to 15%, 14% to 15%.

In some embodiments, the permanganate component may be at least one of a sodium permanganate, a potassium permanganate, a lithium permanganate, a barium permanganate, a hydrogen permanganate, or any combination thereof. In some embodiments, the permanganate component may be a sodium permanganate. In some embodiments, the permanganate component may be a potassium permanganate. In some embodiments, the permanganate component may be a lithium permanganate. In some embodiments, the permanganate component may be a barium permanganate. In some embodiments, the permanganate component may be a hydrogen permanganate.

The composition comprises a plurality of particles. The width percentage (WIP) of the plurality of particles may be less than 500. For example, in some embodiments, the plurality of particles comprises a WIP from 1 to 500, or any range or subrange between 1 and 500. In some embodiments, the plurality of particles comprises a WIP from 1 to 500, 5 to 475, 10 to 450, 15 to 425, 25 to 400, 40 to 375, 50 to 350, 50 to 325, 60 to 300, 70 to 275, 75 to 250, 90 to 225, 100 to 200, 115 to 175, or 125 to 150. In some embodiments, the plurality of particles comprises a WIP from 1 to 450, 1 to 400, 1 to 350, 1 to 300, 1 to 250, 1 to 200, 1 to 150, 1 to 100, 1 to 50, 1 to 25, 1 to 20, 1 to 15, 1 to 10, or 1 to 5. In some embodiments, the plurality of particles comprises a WIP from 5 to 500, 10 to 500, 25 to 500, 50 to 500, 75 to 500, 100 to 500, 150 to 500, 200 to 500, 350 to 500, 400 to 500, 450 to 500, or 475 to 500.

The WIP may be determined according to the formula:

$$WIP = D 50 / ( D 90 - D 10 ) * 100 ,$$

where:
D50 is an 50% average width of an arbitrary distribution function;
D90 is a 90% average width of an arbitrary distribution function;
D10 is a 10% average width of an arbitrary distribution function; and
D90-D10 is the width of an arbitrary distribution function.

The plurality of particles having a WIP less than 500 may cover a substrate surface more uniformly under CMP polishing conditions. The plurality of particles having a WIP less than 500, may increase the removal of an oxidized SiC surface layer. The plurality of particles having a WIP less than 500, may improve the surface quality of the substrate. The plurality of particles having a WIP less than 500, may improve the surface roughness of the substrate. The plurality of particles having a WIP less than 500, may decrease scratches on the substrate.

In some embodiments, the composition comprises 0.01% to 15% by weight of the plurality of particles based on the total weight of the composition, or any range or subrange between 0.01% and 15%. For example, in some embodiments, the plurality of particles by weight based on a total weight of the composition may be 0.05% to 14%, 0.1% to 13%, 0.5% to 12%, 1% to 11%, 2% to 10%, 3% to 9%, 4% to 8%, or 5% to 7%. In some embodiments, the plurality of particles by weight based on a total weight of the composition may be 0.01% to 14%, 0.01% to 13%, 0.01% to 12%, 0.01% to 11%, 0.01% to 10%, 0.01% to 9%, 0.01% to 8%, 0.01% to 7%, 0.01% to 6%, 0.01% to 5%, 0.01% to 4%, 0.01% to 3%, 0.01% to 2%, 0.01% to 1%, 0.01% to 0.09%, 0.01% to 0.08%, 0.01% to 0.07%, 0.01% to 0.06%, 0.01% to 0.05%, 0.01% to 0.04%, 0.01% to 0.03%, or 0.01% to 0.02%. In some embodiments, the plurality of particles by weight based on a total weight of the composition may be 0.02% to 15%, 0.03% to 15%, 0.04% to 15%, 0.05% to 15%, 0.06% to 15%, 0.07% to 15%, 0.08% to 15%, 0.09% to 15%, 0.1% to 15%, 0.5% to 15%, 1% to 15%, 2% to 15%, 3% to 15%, 4% to 15%, 5% to 15%, 6% to 15%, 7% to 15%, 8% to 15%, 9% to 15%, 10% to 15%, 11% to 15%, 12% to 15%, 13% to 15%, or 14% to 15%.

In some embodiments, the composition comprises 0.05% to 10% by weight of the plurality of particles based on the total weight of the composition, or any range or subrange between 0.05% and 10%. For example, in some embodiments, the plurality of particles by weight based on a total weight of the composition may be 0.1% to 9%, 0.5% to 8%, 1% to 7%, 2% to 6%, 3% to 5%, or 4% to 5%. In some embodiments, the plurality of particles by weight based on a total weight of the composition may be 0.05% to 9%, 0.05% to 8%, 0.05% to 7%, 0.05% to 6%, 0.05% to 5%, 0.05% to 4%, 0.05% to 3%, 0.05% to 2%, 0.05% to 1%, 0.05% to 0.09%, 0.05% to 0.08%, 0.05% to 0.07%, or 0.05% to 0.06%. In some embodiments, the plurality of particles by weight based on a total weight of the composition may be 0.06% to 10%, 0.07% to 10%, 0.08% to 10%, 0.09% to 10%, 0.1% to 10%, 0.5% to 10%, 1% to 10%, 2% to 10%, 3% to 10%, 4% to 10%, 5% to 10%, 6% to 10%, 7% to 10%, 8% to 10%, or 9% to 10%.

The plurality of particles comprises at least one of an oxide, metal oxide, a hydroxide, an oxy hydroxide, a nitride, a transition metal carbide, or any combination thereof. In some embodiments, the plurality of particles comprises an oxide. In some embodiments, the plurality of particles comprises a hydroxide. In some embodiments, the plurality of particles comprises an oxy hydroxide. In some embodiments, the plurality of particles comprises a nitride. In some embodiments, the plurality of particles comprises a transition metal carbide.

The plurality of particles may comprise a metal oxide from on or more of, titania, silica, alumina, and/or zirconia.

In some embodiments, the plurality of particles may have a Mohs hardness of less than 6. In some embodiments, the plurality of particles may have a Mohs hardness of less than 5, less than 4, less than 3, less than 2, less than 1. For example, in some embodiments, the plurality of particles may have a Mohs hardness ranging from 1 to 6, or any range or subrange between 1 and 6. In some embodiments, the plurality of particles may have a Mohs hardness of 1 to 5, 1 to 4, 1 to 3, or 1 to 2. In some embodiments, the plurality of particles may have a Mohs hardness of 2 to 6, 3 to 6, 4 to 6, or 5 to 6.

The plurality of particles may have a Z-average particle size of 1 nanometer (nm) to 3000 nm, or any range or subrange between 1 nm and 3000 nm. The Z-average particle size may be referred to as the scattered light intensity-weighted harmonic mean particle diameter which yields from the data analysis algorithm known as cumulants method. The Z-average particle size may be determined according to ISO 22412:2017(en), e.g., by use of a Malvern Zetasizer Nano (Malvern Instruments Ltd., Malvern, UK). For example, the plurality of particles may have a Z-average particle size of 10 nm to 2500 nm, 50 nm to 2000 nm, 100 nm to 1500 nm, 150 nm to 1000 nm, 200 nm to 500 nm, 250 nm to 450 nm, or 300 nm to 400 nm. In some embodiments, the 1 nm to 2750 nm, 1 nm to 2500 nm, 1 nm to 2250 nm, 1 nm to 2000 nm, 1 nm to 1750 nm, 1 nm to 1500 nm, 1 nm to 1250 nm, 1 nm to 1000 nm, 1 nm to 900 nm, 1 nm to 800 nm, 1 nm to 700 nm, 1 nm to 600 nm, 1 nm to 500 nm, 1 nm to 400 nm, 1 nm to 300 nm, 1 nm to 200 nm, 1 nm to 100 nm, 1 nm to 50 nm. In some embodiments, the plurality of particles may have a Z-average particle size of 5 nm to 3000 nm, 10 nm to 3000 nm, 25 nm to 3000 nm, 50 nm to 3000 nm, 100 nm to 3000 nm, 200 nm to 3000 nm, 300 nm to 3000 nm, 400 nm to 3000 nm, 500 nm to 3000 nm, 600 nm to 3000 nm, 700 nm to 3000 nm, 800 nm to 3000 nm, 900 nm to 3000 nm, 1000 nm to 3000 nm, 1100 nm to 3000 nm, 1200 nm to 3000 nm, 1300 nm to 3000 nm, 1400 nm to 3000 nm, 1500 nm to 3000 nm, 1600 nm to 3000 nm, 1700 nm to 3000 nm, 1800 nm to 3000 nm, 1900 nm to 3000 nm, 2000 nm to 3000 nm, 2100 nm to 3000 nm, 2200 nm to 3000 nm, 2300 nm to 3000 nm, 2400 nm to 3000 nm, 2500 nm to 3000 nm, 2600 nm to 3000 nm, 2700 nm to 3000 nm, 2800 nm to 3000 nm, or 2900 nm to 3000 nm.

In some embodiments, the composition further comprises a nitrate. The nitrate adjusts the pH value of the composition. The nitrate may acidify the composition.

In some embodiments, the nitrate comprises at least one of a metal nitrate, a metal oxynitrate, or any combination thereof. In some embodiments, the nitrate may be a metal nitrate. Non-limiting examples of the metal nitrate include, for example and without limitation, calcium nitrate, magnesium nitrate, iron (III) nitrate and copper (II) nitrate. In some embodiments, the nitrate may be a metal oxynitrate. Non-limiting examples of the metal oxynitrate include, for example and without limitation, zirconium oxynitrate, nickel oxynitrate, and hafnium oxynitrate.

In some embodiments, the nitrate comprises 0.05% to 5% by weight based on a total weight of the composition, or any range or subrange between 0.05% and 5%. For example, in some embodiments, the nitrate by weight based on a total weight of the composition may be 0.1% to 4%, 0.5% to 3%, or 1% to 2%. In some embodiments, the nitrate by weight based on a total weight of the composition may be 0.05% to 4.8%, 0.05% to 4.6%, 0.05% to 4.4%, 0.05% to 4.2%, 0.05% to 4%, 0.05% to 3.8%, 0.05% to 3.6%, 0.05% to 3.4%, 0.05% to 3.2%, 0.05% to 3%, 0.05% to 2.8%, 0.05% to 2.6%, 0.05% to 2.4%, 0.05% to 2.2%, 0.05% to 2%, 0.05% to 1.8%, 0.05% to 1.6%, 0.05% to 1.4%, 0.05% to 1.2%, 0.05% to 1%, 0.05% to 0.8%, 0.05% to 0.6%, 0.05% to 0.4%, 0.05% to 0.2%, 0.05% to 0.1%, 0.05% to 0.09%, 0.05% to 0.08%, 0.05% to 0.07%, or 0.05% to 0.06%. In some embodiments, the nitrate by weight based on a total weight of the composition may be 0.05% to 5%, 0.06% to 5%, 0.07% to 5%, 0.08% to 5%, 0.09% to 5%, 0.10% to 5%, 0.20% to 5%, 0.30% to 5%, 0.40% to 5%, 0.50% to 5%, 0.60% to 5%, 0.70% to 5%, 0.80% to 5%, 0.90% to 5%, 1% to 5%, 1.2% to 5%, 1.4% to 5%, 1.6% to 5%, 1.8% to 5%, 2% to 5%, 2.2% to 5%, 2.4% to 5%, 2.6% to 5%, 2.8% to 5%, 3% to 5%, 3.2% to 5%, 3.4% to 5%, 3.6% to 5%, 3.8% to 5%, 4% to 5%, 4.2% to 5%, 4.4% to 5%, 4.6% to 5%, or 4.8% to 5%.

In some embodiments, the nitrate comprises 0.05% to 2% by weight based on a total weight of the composition, or any range or subrange between 0.05% and 2%. For example, the nitrate by weight based on a total weight of the composition may be 0.1% to 2%, 0.5% to 1.5%, or 0.8% to 1%. In some embodiments, the nitrate by weight based on a total weight of the composition may be 0.05% to 1.8%, 0.05% to 1.6%, 0.05% to 1.4%, 0.05% to 1.2%, 0.05% to 1%, 0.05% to 0.8%, 0.05% to 0.6%, 0.05% to 0.4%, 0.05% to 0.2%, 0.05% to 0.1%, 0.05% to 0.09%, 0.05% to 0.08%, 0.05% to 0.07%, or 0.05% to 0.06%. In some embodiments, the nitrate by weight based on a total weight of the composition may be 0.05% to 2%, 0.06% to 2%, 0.07% to 2%, 0.08% to 2%, 0.09% to 2%, 0.10% to 2%, 0.20% to 2%, 0.30% to 2%, 0.40% to 2%, 0.50% to 2%, 0.60% to 2%, 0.70% to 2%, 0.80% to 2%, 0.90% to 2%, 1% to 2%, 1.2% to 2%, 1.4% to 2%, 1.6% to 2%, or 1.8% to 2%.

In some embodiments, the composition has a pH of 1 to 9, or any range or subrange between 1 and 9. In some embodiments, the composition has a pH of 1 to 8. In some embodiments, the composition has a pH of 1 to 7. In some embodiments, the composition has a pH of 1 to 6. In some embodiments, the composition has a pH of 1 to 5. In some embodiments, the composition has a pH of 1 to 4. In some embodiments, the composition has a pH of 1 to 3. In some embodiments, the composition has a pH of 1 to 2. In some embodiments, the composition has a pH of 2 to 9. In some embodiments, the composition has a pH of 3 to 9. In some embodiments, the composition has a pH of 4 to 9. In some embodiments, the composition has a pH of 5 to 9. In some embodiments, the composition has a pH of 6 to 9. In some embodiments, the composition has a pH of 7 to 9. In some embodiments, the composition has a pH of 8 to 9.

In some embodiments, when the composition is contacted with a substrate comprising a silicon carbide layer, at 10 milliliter per minute (mL/min) to 200 mL/min flow rate, 2 PSI to 10 PSI Polishing DF, 25 RPM to 200 RPM Platen rotation speed, 5 min to 90 min of polishing time, the composition may remove at least a portion of the silicon carbide layer at a removal rate of 0.1 micrometers per hour (μm/hr) to 14 μm/hr.

Some embodiments relate to systems. A system comprises a composition, a substrate comprising a silicon carbide layer, and a chemical mechanical planarization (CMP) apparatus.

The system comprises a composition. As disclosed herein, the composition comprises at least 5% by weight of a permanganate component based on a total weight of the composition and a plurality of particles. The plurality of particles has a width percentage (WIP) determined according to the formula:

$$WIP = {D}_{50} / ( {D}_{90} - {D}_{10} ) * 100 ,$$

wherein the WIP of the plurality of particles is less than 500.

The system comprises a substrate. The substrate comprises a silicon carbide layer. In some embodiments, the silicon carbide layer may be on a surface of the substrate. The surface of the substrate may be polished using a CMP method. The silicon substrate to be polished using the CMP method, may have at least one layer of a silicon carbide. The substrate may include, but are not limited to, flat panel displays, integrated circuits, memory, or rigid disks, metals, interlayer dielectric (ILD) devices, semiconductors, micro-electro-mechanical systems, ferroelectrics, and magnetic heads.

The silicon carbide may be a single crystal or a polycrystalline. The silicon carbide may have different types of crystal structures, each having its own distinct set of electronic properties. Only a few of these polytypes, however, can be reproduced in a form acceptable for use as semiconductors. Such polytypes may be either cubic (e.g., 3C silicon carbide) or non-cubic (e.g., 4H silicon carbide, 6H silicon carbide).

The system comprises a CMP apparatus. The CMP apparatus may be configured to bring the composition and the substrate into contact to remove at least a portion of the silicon carbide layer from the substrate.

The CMP apparatus may be a polishing pad. Any conventional polishing pad may be used in a CMP method for removing at least a portion of the silicon carbide substrate from the surface of the substrate. Polishing pads may be, for example, woven and non-woven polishing pads. Polishing pads may comprise a polymer of varying density, hardness, thickness, compressibility, have an ability to rebound upon compression, and compression modulus. Suitable polymers include, for example, polyvinylchloride, polyvinylfluoride, nylon, fluorocarbon, polycarbonate, polyester, polyacrylate, polyether, polyethylene, polyamide, polyurethane, polystyrene, polypropylene, conformed products thereof, and mixtures thereof. The polishing pad can have any suitable configuration. For example, the polishing pad may be circular and, when in use, may have a rotational motion about an axis perpendicular to the plane defined by the surface of the pad. The polishing pad can be cylindrical, the surface of which acts as the polishing surface, and, when in use, may have a rotational motion about the central axis of the cylinder. The polishing pad may be in the form of an endless belt, which, when in use, may have a linear motion with respect to the cutting edge being polished. The polishing pad may have any suitable shape and, when in use, have a reciprocating or orbital motion along a plane or a semicircle.

In some embodiments, when the composition is contacted with a substrate comprising a silicon carbide layer at the following conditions: at 10 mL/min to 200 mL/min flow rate, 2 PSI to 10 PSI, 25 RPM to 200 RPM Platen rotation speed, 5 min to 90 min of polishing time, the composition removes at least a portion of the silicon carbide layer at a removal rate of 0.1 μm/hr to 14 μm/hr.

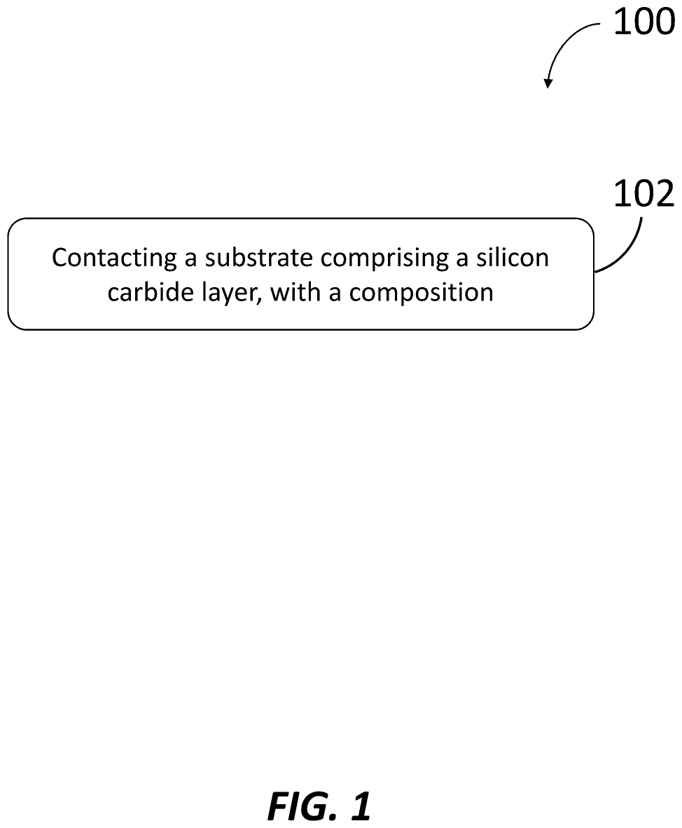

FIG. 1 is a flow diagram of a method for polishing silicon carbide. At step 102, in some embodiments, the method 100 comprises the step of: contacting a substrate comprising a silicon carbide layer, with a composition, under conditions sufficient to remove at least a portion of the silicon carbide layer.

In some embodiments, the contacting comprises bringing the composition and the substrate into close or immediate proximity. In some embodiments, the contacting comprises bringing the composition and the substrate into direct physical contact. In some embodiments, the contacting comprises rubbing the composition and the substrate into close or immediate proximity. In some embodiments, the contacting comprises rubbing the composition and the substrate in direct contact. In some embodiments, the contacting comprises pressing the composition and the substrate into close or immediate proximity. In some embodiments, the contacting comprises pressing the composition and the substrate into direct contact. In some embodiments, the contacting comprises rubbing the composition and the substrate into close or immediate proximity. In some embodiments, the contacting comprises rubbing the composition and the substrate into direct contact. In some embodiments, the composition, and the substrate are contacted sequentially, in any order. In some embodiments, the composition, and the substrate are contacted substantially simultaneously or simultaneously.

As described herein, the composition comprises a plurality of particles and a silicon carbide substrate. In some embodiments, a width percentage (WIP) of the plurality of particles is less than 500, as determined according to the formula:

$$WIP = D 50 / ( D 90 - D 10 ) * 100 ,$$

where:
D50 is an 50% average width of an arbitrary distribution function;
D90 is a 90% average width of an arbitrary distribution function;
D10 is a 10% average width of an arbitrary distribution function; and
D90-D10 is the width of an arbitrary distribution function.

In some embodiments, conditions sufficient to remove at least a portion of the silicon carbide layer may include, when the composition is contacted with a substrate comprising a silicon carbide layer at 10 mL/min to 200 mL/min flow rate, 2 PSI to 10 PSI, 25 RPM to 200 RPM Platen rotation speed, 5 min to 90 min of polishing time, the composition removing at least a portion of the silicon carbide layer at a removal rate of 0.1 μm/hr to 14 μm/hr.

In some embodiments, the composition may be contacted with a substrate comprising a silicon layer at flow rate in a range of 10 milliliters per minute (mL/min) to 200 mL/min, or any range or subrange between 10 mL/min and 200 mL/min. For example, in some embodiments, the composition may be contacted with a substrate comprising a silicon layer at flow rate of 20 mL/min to 190 mL/min, 30 mL/min to 180 mL/min, 40 mL/min to 170 mL/min, 50 mL/min to 160 mL/min, 60 mL/min to 150 mL/min, 70 mL/min to 140 mL/min, 80 mL/min to 130 mL/min, 90 mL/min to 120 mL/min, 100 mL/min to 110 mL/min. In some embodiments, the composition may be contacted with a substrate comprising a silicon layer at flow rate in a range of 10 mL/min to 190 mL/min, 10 mL/min to 180 mL/min, 10 mL/min to 170 mL/min, 10 mL/min to 160 mL/min, 10 mL/min to 150 mL/min, 10 mL/min to 140 mL/min, 10 mL/min to 130 mL/min, 10 mL/min to 120 mL/min, 10 mL/min to 110 mL/min, 10 mL/min to 100 mL/min, 10 mL/min to 90 mL/min, 10 mL/min to 80 mL/min, 10 mL/min to 70 mL/min, 10 mL/min to 60 mL/min, 10 mL/min to 50 mL/min, 10 mL/min to 40 mL/min, 10 mL/min to 30 mL/min, or 10 mL/min to 20 mL/min. In some embodiments, the composition may be contacted with a substrate comprising a silicon layer at flow rate in a range of 20 mL/min to 200 mL/min, 30 mL/min to 200 mL/min, 40 mL/min to 200 mL/min, 50 mL/min to 200 mL/min, 60 mL/min to 200 mL/min, 70 mL/min to 200 mL/min, 80 mL/min to 200 mL/min, 90 mL/min to 200 mL/min, 100 mL/min to 200 mL/min, 110 mL/min to 200 mL/min, 120 mL/min to 200 mL/min, 130 mL/min to 200 mL/min, 140 mL/min to 200 mL/min, 150 mL/min to 200 mL/min, 160 mL/min to 200 mL/min, 170 mL/min to 200 ml/min, 180 mL/min to 200 mL/min, or 190 mL/min to 200 mL/min.

In some embodiments, the composition may be contacted with a substrate comprising a silicon layer at a pressure in a range of 2 to 10 PSI, or any range or subrange between 2 PSI and 10 PSI. In some embodiments, the composition may be contacted with a substrate comprising a silicon layer at a pressure in a range of 2 PSI and 9 PSI. In some embodiments, the composition may be contacted with a substrate comprising a silicon layer at a pressure in a range of 2 PSI and 8 PSI. In some embodiments, the composition may be contacted with a substrate comprising a silicon layer at a pressure in a range of 2 PSI and 7 PSI. In some embodiments, the composition may be contacted with a substrate comprising a silicon layer at a pressure in a range of 2 PSI and 6 PSI. In some embodiments, the composition may be contacted with a substrate comprising a silicon layer at a pressure in a range of 2 PSI and 5 PSI. In some embodiments, the composition may be contacted with a substrate comprising a silicon layer at a pressure in a range of 2 PSI and 4 PSI. In some embodiments, the composition may be contacted with a substrate comprising a silicon layer at a pressure in a range of 2 PSI and 3 PSI.

In some embodiments, the composition may be contacted with a substrate comprising a silicon layer at a Platen rotation speed in a range of 25 RPM to 200 RPM, or any range or subrange between 25 RPM to 200 RPM. For example, in some embodiments, the composition may be contacted with a substrate comprising a silicon layer at a Platen rotation speed in a range of 50 RPM to 175 RPM, 75 RPM to 150 RPM, or 100 RPM to 125 RPM. In some embodiments, the composition may be contacted with a substrate comprising a silicon layer at a Platen rotation speed in a range of 25 RPM to 175 RPM, 25 RPM to 150 RPM, 25 RPM to 125 RPM, 25 RPM to 100 RPM, 25 RPM to 75 RPM, or 25 RPM to 50 RPM. In some embodiments, the composition may be contacted with a substrate comprising a silicon layer at a Platen rotation speed in a range of 25 RPM to 175 RPM, 25 RPM to 150 RPM, 25 RPM to 125 RPM, 25 RPM to 100 RPM, 25 RPM to 75 RPM, or 25 RPM to 50 RPM.

In some embodiments, the composition removes at least a portion of the silicon carbide layer at a removal rate in a range of 0.1 micrometer per hour (μm/hr) to 14 μm/hr, or any range or subrange between 0.1 μm/hr to 14 μm/hr. For example, in some embodiments, the composition removes at least a portion of the silicon carbide layer at a removal rate in a range of 0.5 μm/hr to 13 μm/hr, 1 μm/hr to 12 μm/hr, 2 μm/hr to 11 μm/hr, 3 μm/hr to 10 μm/hr, 4 μm/hr to 9 μm/hr, 5 μm/hr to 8 μm/hr, or 6 μm/hr to 7 μm/hr. In some embodiments, the composition removes at least a portion of the silicon carbide layer at a removal rate in a range of 0.5 μm/hr to 14 μm/hr, 1 μm/hr to 14 μm/hr, 2 μm/hr to 14 μm/hr, 3 μm/hr to 14 μm/hr, 4 μm/hr to 14 μm/hr, 5 μm/hr to 14 μm/hr, or 6 μm/hr to 14 μm/hr, 7 μm/hr to 14 μm/hr, 8 μm/hr to 14 μm/hr, 9 μm/hr to 14 μm/hr, 10 μm/hr to 14 μm/hr, 11 μm/hr to 14 μm/hr, 12 μm/hr to 14 μm/hr, or 13 μm/hr to 14 μm/hr. In some embodiments, the composition removes at least a portion of the silicon carbide layer at a removal rate in a range of 0.1 μm/hr to 13 μm/hr, 0.1 μm/hr to 12 μm/hr, 0.1 μm/hr to 11 μm/hr, 0.1 μm/hr to 10 μm/hr, 0.1 μm/hr to 9 μm/hr, 0.1 μm/hr to 8 μm/hr, 0.1 μm/hr to 7 μm/hr, 0.1 μm/hr to 6 μm/hr, 0.1 μm/hr to 5 μm/hr, 0.1 μm/hr to 4 μm/hr, 0.1 μm/hr to 3 μm/hr, 0.1 μm/hr to 2 μm/hr, or 0.1 μm/hr to 1 μm/hr.

The material removal rate can be determined by the change in mass of the substrate before and after polishing using the following equation:

$$MRR = \frac{Δ m}{{ρ}_{substrate} π {r}^{2} t} ,$$

wherein:
Δm is the change in mass of the substrate before and after polishing,
ρsubstrate is the density of the substrate,
r² is the radius of the substrate,
t is the polishing time.

The change in mass of the substrate before and after is divided by the time spent polishing to calculate the material removal rate. The mass of the substrate may be measured using a benchtop scale.

In some embodiments, the removal rate may increase from 10% using a composition with a WIP of the plurality of particles greater than 500 to 30% using the composition with a WIP of the plurality of particles less than 500 disclosed herein. In some embodiments, the removal rate using the composition having a WIP of the plurality of particles less than 500 disclosed herein, is greater than a composition having a WIP of the plurality of particles greater than 500.

In some embodiments, the composition removes at least a portion of the silicon carbide layer at a polishing time of 5 minutes to 90 minutes, or any range or subrange between 5 minutes to 90 minutes. For example, in some embodiments, the composition removes at least a portion of the silicon carbide layer at a polishing time ranging from 10 minutes to 80 minutes, 15 minutes to 70 minutes, 20 minutes to 60 minutes, 25 minutes to 50 minutes, or 30 minutes to 40 minutes. In some embodiments, the composition removes at least a portion of the silicon carbide layer at a polishing time ranging from 5 minutes to 80 minutes, 5 minutes to 70 minutes, 5 minutes to 60 minutes, 5 minutes to 50 minutes, 5 minutes to 40 minutes, 5 minutes to 30 minutes, 5 minutes to 20 minutes, or 5 minutes to 10 minutes. In some embodiments, the composition removes at least a portion of the silicon carbide layer at a polishing time ranging from 15 minutes to 90 minutes, 25 minutes to 90 minutes, 35 minutes to 90 minutes, 45 minutes to 90 minutes, 55 minutes to 90 minutes, 65 minutes to 90 minutes, 75 minutes to 90 minutes, or 85 minutes to 90 minutes.

The surface roughness after removing at least a portion of the silicon carbide substrate may provide for formation of a soften layer on the particle surface which prevents damage of the surface of the substrate during polishing without negatively impacting the high material removal rates. Roughness may be calculated as RMS roughness by AFM metrology (5×5 scan, 1 Hz scan rate).

Any one or more of the embodiments disclosed herein shall be understood to be combinable without departing from the scope or spirit of the disclosure.

### EXAMPLES

### Example 1

Various compositions for polishing silicon carbide wafers were prepared and the performance of each was evaluated. The compositions are summarized in the table below as Samples 1-8. Silicon faces of silicon carbide (SiC) wafers were polished with Samples 1-8 using a single wafer polisher (GnP Poli 300). Each wafer was contacted with each Sample using a D100 pad for a duration of 10 minutes at a platen speed of 90 rotations per minute (RPM). During polishing, each Sample was supplied at a slurry flow rate of 50 milliliter per minute (mL/min), with 4 PSI of pressure being applied to each wafer. Between each polishing, the pad was conditioned ex-situ. The slurry used for the sample testing had metal oxide particles in a permanganate slurry used for polishing silicon carbide. Each of Samples 1-8 was prepared with a particle size distribution as summarized in Table 1 below. Table 2 below summarizes the polishing conditions.

TABLE 1
Particle Size Distribution

| | D10 (nm) | D50 (nm) | D90 (nm) | WIP= | MRR (nm/hr) |
|---|---|---|---|---|---|
| Sample 1 | 578 | 745 | 945 | 203 | 1000 |
| Sample 2 | 734 | 1500 | 5630 | 0.306 | 1376 |
| Sample 3 | 1480 | 1890 | 2430 | 199 | 1512 |
| Sample 4 | 86.4 | 744 | 1200 | 67 | 1552 |
| Sample 5 | 104 | 664 | 1070 | 69 | 1582 |
| Sample 6 | 525 | 704 | 947 | 167 | 1468 |
| Sample 7 | 52 | 56 | 60 | 700 | 451 |
| Sample 8 | 33 | 36 | 38 | 720 | 404 |

TABLE 2
Polishing Conditions

| Polisher | GnP Poli 300 (Single Wafer Polisher) | |
|---|---|---|
| Pad | D100 | |
| Wafers | Silicon Carbide Si face (4″ diameter) | |
| Wafer Pressure | 4 | psi |
| Carrier/Platen Speed | 90/90 | |
| Conditioning | Ex-Situ | |
| Polishing Time | 10 | min |
| Composition Flow Rate | ~50 | mL/min |

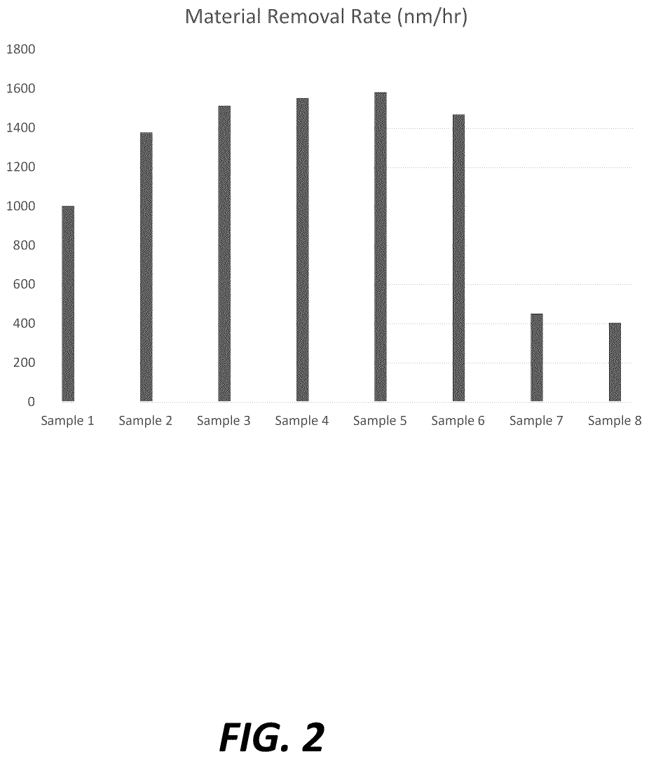

FIG. 2 is a graphical view of material removal rates for various samples with different width percentages, according to some embodiments. As shown in FIG. 2, Sample 4 and Sample 5 had the highest material removal rate. Sample 1 had the lowest rate material rate. Each Sample had a WIP below 500 and each exhibited an increased material removal rate relative to compositions having WIP greater than 500. In contrast, Sample 7 and 8 have higher WIP and therefore have a much Lower removal rate.

### Example 2

In one example, the composition comprises particles of a silica, alumina and a zirconia particle with a WIP of _203_. The composition further comprises a nitrate and _<5% permanganate with acidic pH. The composition is used to polish a silicon carbide surface with the removal rate of _1 μm/hr_. Preferred composition improves surface roughness to _<5 nm_.

### Example 3

In another example, the composition comprises alumina and zirconia particle with a WIP of 67. The composition further comprises a nitrate and <15% permanganate with pH 2.3. The composition is used to polish a Silicon carbide (SiC) surface that enhances removal rate to 50% compared to example 2 and improves surface roughness values to below 3 nm.

### Example 4

The composition in example 4, comprises zirconia particles with a WIP of 0.306. The composition further comprises a nitrate and 10-15% of permanganate with pH3.4. The composition used to polish a Silicon carbide (SiC) surface that improves surface roughness of the material to <5 A and enhances removal rate ˜1.3 μm/hr.

### ASPECTS

Various Aspects are described below. It is to be understood that any one or more of the features recited in the following Aspect(s) can be combined with any one or more other Aspect(s).
Aspect 1. A composition comprising:
   at least 5% by weight of a permanganate component based on a total weight of the composition; and
   a plurality of particles,
      wherein the plurality of particles has a width percentage (WIP) determined according to the formula:

$$WIP = {D}_{50} / ( {D}_{90} - {D}_{10} ) * 100 ,$$

wherein the WIP of the plurality of particles is less than 500.
Aspect 2. The composition according to Aspect 1, the composition comprises 5% to 20% by weight of the permanganate component based on the total weight of the composition.
Aspect 3. The composition according to any one of Aspects 1-2, wherein the composition comprises 5% to 15% by weight of the permanganate component based on the total weight of the composition.
Aspect 4. The composition according to any one of Aspects 1-3, wherein the composition comprises 0.01% to 15% by weight of the plurality of particles based on the total weight of the composition.
Aspect 5. The composition according to any one of Aspects 1-4, wherein the composition comprises 0.05% to 10% by weight of the plurality of particles based on the total weight of the composition.
Aspect 6. The composition according to any one of Aspects 1-5, wherein the permanganate component comprises at least one of a sodium permanganate, a potassium permanganate, a lithium permanganate, a barium permanganate, a hydrogen permanganate, or any combination thereof.
Aspect 7. The composition according to any one of Aspects 1-6, wherein the plurality of particles comprises at least one of an oxide, a hydroxide, an oxy hydroxide, a nitride, a transition metal carbide, or any combination thereof.
Aspect 8. The composition according to any one of Aspects 1-7, wherein the composition further comprises a nitrate component.
Aspect 9. The composition according to any one of Aspects 1-8, wherein the nitrate component comprises at least one of a metal nitrate, a metal oxynitrate, or any combination thereof.
Aspect 10. The composition according to any one of Aspects 1-9, wherein the composition further comprises 0.05% to 5% by weight of a nitrate component based on a total weight of the composition.
Aspect 11. The composition according to any one of Aspects 1-10, wherein the composition further comprises 0.05% to 2% by weight of a nitrate component based on a total weight of the composition.
Aspect 12. The composition according to any one of Aspects 1-11, wherein, when the composition is contacted with a substrate comprising a silicon carbide layer, at 10 milliliter per minute (mL/min) to 200 mL/min flow rate, 2 PSI to 10 PSI Polishing DF, 25 RPM to 200 RPM Platen rotation speed, 5 min to 90 min of polishing time, the composition removes at least a portion of the silicon carbide layer at a removal rate of 0.1 micrometers per hour (μm/hr) to 14 μm/hr.
Aspect 13. The method according to any one of Aspects 1-12, wherein the composition has a pH of 1 to 9.
Aspect 14. A system comprising:
   a composition,
      wherein the composition comprises:
         at least 5% by weight of a permanganate component based on a total weight of the composition; and
   a plurality of particles,
      wherein the plurality of particles has a width percentage (WIP) determined according to the formula:

$$WIP = {D}_{50} / ( {D}_{90} - {D}_{10} ) * 100 ,$$

wherein the WIP of the plurality of particles is less than 500;
a substrate comprising a silicon carbide layer; and
a chemical mechanical planarization (CMP) apparatus,
   wherein the CMP apparatus is configured to bring the composition and the substrate into contact to remove at least a portion of the silicon carbide layer from the substrate.
Aspect 15. The system according to Aspect 14, wherein the composition comprises 0.01% to 15% by weight of the plurality of particles based on the total weight of the composition.
Aspect 16. The system according to any one of Aspects 14-15, wherein the permanganate component comprises at least one of a sodium permanganate, a potassium permanganate, a lithium permanganate, a barium permanganate, a hydrogen permanganate, or any combination thereof.
Aspect 17. The system according to any one of Aspects 14-16, wherein, when the composition is contacted with a substrate comprising a silicon carbide layer, at 10 milliliter per minute (mL/min) to 200 mL/min flow rate, 2 PSI to 10 PSI, 25 RPM to 200 RPM Platen rotation speed, 5 min to 90 min of polishing time, the composition removes at least a portion of the silicon carbide layer at a removal rate of 0.1 micrometers per hour (μm/hr) to 14 μm/hr.
Aspect 18. A method comprising:
   contacting a substrate comprising a silicon carbide layer, with a composition, under conditions sufficient to remove at least a portion of the silicon carbide layer,
      wherein the composition comprises:
         at least 5% by weight of a permanganate component based on a total weight of the composition; and
         a plurality of particles,
         wherein the plurality of particles has a width percentage (WIP) determined according to the formula:

$$WIP = D 50 / ( {D}_{90} - {D}_{10} ) * 100 ,$$

wherein the WIP of the plurality of particles is less than 500.
Aspect 19. The method according to Aspect 18, wherein the permanganate component comprises at least one of a sodium permanganate, a potassium permanganate, a lithium permanganate, a barium permanganate, a hydrogen permanganate, or any combination thereof.
Aspect 20. The method according to any one of Aspects 18-19, wherein, when the composition is contacted with a substrate comprising a silicon carbide layer, at 10 milliliter per minute (mL/min) to 200 mL/min flow rate, 2 PSI to 10 PSI, 25 RPM to 200 RPM Platen rotation speed, 5 min to 90 min of polishing time, the composition removes at least a portion of the silicon carbide layer at a removal rate of 0.1 micrometers per hour (μm/hr) to 14 μm/hr.

What is claimed is:

1. A composition comprising:
at least 5% by weight of a permanganate component based on a total weight of the composition; and
a plurality of particles
wherein the plurality of particles has a width percentage (WIP) determined according to the formula:
$$WIP = {D}_{50} / ( {D}_{90} - {D}_{10} ) * 100 ,$$
wherein the WIP of the plurality of particles is less than 500.

2. The composition of claim 1, wherein the composition comprises 5% to 20% by weight of the permanganate component based on the total weight of the composition.

3. The composition of claim 1, wherein the composition comprises 5% to 15% by weight of the permanganate component based on the total weight of the composition.

4. The composition of claim 1, wherein the composition comprises 0.01% to 15% by weight of the plurality of particles based on the total weight of the composition.

5. The composition of claim 1, wherein the composition comprises 0.05% to 10% by weight of the plurality of particles based on the total weight of the composition.

6. The composition of claim 1, wherein the permanganate component comprises at least one of a sodium permanganate, a potassium permanganate, a lithium permanganate, a barium permanganate, a hydrogen permanganate, or any combination thereof.

7. The composition of claim 1, wherein the plurality of particles comprises at least one of an oxide, metal oxide, a hydroxide, an oxy hydroxide, a nitride, a transition metal carbide, or any combination thereof.

8. The composition of claim 1, wherein the plurality of particles comprises titania, silica, alumina, and/or zirconia.

9. The composition of claim 8, wherein the nitrate component comprises at least one of a metal nitrate, a metal oxynitrate, or any combination thereof.

10. The composition of claim 8, wherein the composition further comprises 0.05% to 5% by weight of a nitrate component based on a total weight of the composition.

11. The composition of claim 8, wherein the composition further comprises 0.05% to 2% by weight of a nitrate component based on a total weight of the composition.

12. The composition of claim 1, wherein, when the composition is contacted with a substrate comprising a silicon carbide layer, at 10 milliliter per minute (mL/min) to 200 mL/min flow rate, 2 PSI to 10 PSI, 25 RPM to 200 RPM Platen rotation speed, 5 min to 90 min of polishing time, the composition removes at least a portion of the silicon carbide layer at a removal rate of 0.1 micrometers per hour (μm/hr) to 14 μm/hr.

13. The composition of claim 1, wherein the composition has a pH of 1 to 9.

14. A system comprising:
a composition,
wherein the composition comprises:
at least 5% by weight of a permanganate component based on a total weight of the composition; and
a plurality of particles,
wherein the plurality of particles has a width percentage (WIP) determined according to the formula:
$$WIP = {D}_{50} / ( {D}_{90} - {D}_{10} ) * 100 ,$$
wherein the WIP of the plurality of particles is less than 500;
a substrate comprising a silicon carbide layer; and
a chemical mechanical planarization apparatus,
wherein the chemical mechanical planarization apparatus is configured to bring the composition and the substrate into contact to remove at least a portion of the silicon carbide layer from the substrate.

15. The system of claim 14, wherein the composition comprises 0.01% to 15% by weight of the plurality of particles based on the total weight of the composition.

16. The system of claim 14, wherein the permanganate component comprises at least one of a sodium permanganate, a potassium permanganate, a lithium permanganate, a barium permanganate, a hydrogen permanganate, or any combination thereof.

17. The system of claim 14, wherein, when the composition is contacted with a substrate comprising a silicon carbide layer, at 10 milliliter per minute (mL/min) to 200 mL/min flow rate, 2 PSI to 10 PSI, 25 RPM to 200 RPM Platen rotation speed, 5 min to 90 min of polishing time, the composition removes at least a portion of the silicon carbide layer at a removal rate of 0.1 micrometers per hour (μm/hr) to 14 μm/hr.

18. A method comprising:
contacting a substrate comprising a silicon carbide layer, with a composition, under conditions sufficient to remove at least a portion of the silicon carbide layer,
wherein the composition comprises:
at least 5% by weight of a permanganate component based on a total weight of the composition; and
a plurality of particles,
wherein the plurality of particles has a width percentage (WIP) determined according to the formula:
$$WIP = D 50 / ( {D}_{90} - {D}_{10} ) * 100 ,$$
wherein the WIP of the plurality of particles is less than 500.

19. The method of claim 18, wherein the permanganate component comprises at least one of a sodium permanganate, a potassium permanganate, a lithium permanganate, a barium permanganate, a hydrogen permanganate, or any combination thereof.

20. The method of claim 18, wherein, when the composition is contacted with a substrate comprising a silicon carbide layer, at 10 milliliter per minute (mL/min) to 200 mL/min flow rate, 2 PSI to 10 PSI, 25 RPM to 200 RPM Platen rotation speed, 5 min to 90 min of polishing time, the composition removes at least a portion of the silicon carbide layer at a removal rate of 0.1 micrometers per hour (μm/hr) to 14 μm/hr.
